(19) United States
(12) Patent Application Publication
(10) Pub. No.: US 2025/0271485 A1
(43) Pub. Date: Aug. 28, 2025

(54) SYSTEM FOR ESTIMATING PARTIAL DISCHARGE OCCURRENCE LOCATION BASED ON PRECISION TIME-SYNCHRONIZATION PROTOCOL (PTP)

(71) Applicant: LS ELECTRIC CO., LTD., Anyang-si, Gyeonggi-do (KR)

(72) Inventors: Yeoung Duk SEO, Anyang-si, Gyeonggi-do (KR); Hyun Ho KWON, Anyang-si, Gyeonggi-do (KR); Ha Young LEE, Anyang-si, Gyeonggi-do (KR); Gwang Goo KANG, Anyang-si, Gyeonggi-do (KR); Jin Ho LEE, Anyang-si, Gyeonggi-do (KR); Chang Hwan JIN, Anyang-si, Gyeonggi-do (KR); Yong Jin JI, Anyang-si, Gyeonggi-do (KR)

(21) Appl. No.: 18/696,460

(22) PCT Filed: Sep. 26, 2022
(86) PCT No.: PCT/KR2022/014339

§ 371 Date: Sep. 6, 2024

(30) Foreign Application Priority Data
Dec. 14, 2021 (KR) 10-2021-0178496

(51) Int. Cl. G01R 31/08; G01R 31/12

(52) U.S. Cl. CPC G01R 31/083; G01R 31/1272

(57) ABSTRACT

A system for estimating a partial discharge occurrence location, according to an embodiment of the present disclosure, comprises: a plurality of data acquisition apparatuses that are installed in one area of a measurement target, and simultaneously acquire sensing data via time synchronization using a precision time-synchronization protocol (PTP); and a determination apparatus that determines a partial discharge occurrence location of the measurement target by using a plurality of pieces of sensing data received from the plurality of data acquisition apparatuses.

### CROSS-REFERENCE TO RELATED APPLICATIONS

This application is a National Stage of International Application No. PCT/KR2022/014339, filed on Sep. 26, 2022, which claims priority to and the benefit of Korean Patent Application No. 10-2021-0178496, filed on Dec. 14, 2021, the disclosures of which is incorporated herein by reference in its entirety.

### FIELD

The present disclosure relates to a system for estimating a partial discharge occurrence location based on a precision time-synchronization protocol (PTP).

### BACKGROUND

Electric power facilities such as switchboards, transformers, and gas insulated switchgear (GIS) are building insulation systems to prevent safety accidents. However, partial discharge (PD) may occur due to defects such as insulation deterioration caused by long-term operation of electric power facilities or cracks caused by electrical or mechanical stress.

Partial discharges occurring in insulators can progress to insulation breakdown and lead to system accidents, so early detection and accurate location identification are important.

Determination of the location of partial discharge was possible by field experts using measuring equipment to measure directly from various points on the insulator. This raised safety issues because field experts had to be directly involved, and there were economic and physical limits to the measuring equipment that could be installed in power facilities.

Therefore, attempts were made to replace it with an online diagnosis system, but since there was no precise time synchronization method for multiple measuring equipment, it was possible to determine whether a partial discharge occurred, but it was difficult to determine the local location of the partial discharge within the power facility.

With the recent emergence of smart factory and power system automation standards, the Precision Time-synchronization Protocol (PTP), which allows time synchronization down to nanoseconds, has been proposed. This maintains interoperability between apparatuses used in the power system and enables smart protection and online diagnostic technologies under a precisely synchronized time axis.

### SUMMARY

The present disclosure is directed to providing a system for estimating a partial discharge occurrence location without separate hardware ring by performing network-based time synchronization through PTP.

A system for estimating a partial discharge occurrence location, according to an embodiment of the present disclosure, comprises: a plurality of data acquisition apparatuses that are installed in one area of a measurement target, and simultaneously acquire sensing data via time synchronization using a precision time-synchronization protocol (PTP); and a determination apparatus that determines a partial discharge occurrence location of the measurement target by using a plurality of pieces of sensing data received from the plurality of data acquisition apparatuses.

The plurality of data acquisition apparatuses may consist of one master apparatus and a plurality of slave apparatuses, and each of the plurality of data acquisition apparatuses may include: a precision time synchronizer configured to transmit a time synchronization signal based on PTP based on the master apparatus; a sensor data processor configured to collect the sensing data based on a time synchronization signal received from the precision time synchronizer and process the collected sensing data; and a PRPD generator configured to generate PRPD data by mapping the plurality of pieces of processed sensing data received from the sensor data processor for a predefined time and a time synchronization signal received from the precision time synchronizer.

The determination apparatus may include: a communicator; and a processor configured to: receive the plurality of pieces of PRPD data from the plurality of data acquisition apparatuses through the communicator, identify a pattern corresponding to the plurality of pieces of received

PRPD data, arrange the plurality of pieces of PRPD data in chronological order based on the mapped time synchronization signal, and identify the partial discharge occurrence location based on the installation locations of the plurality of data acquisition apparatuses and the plurality of pieces of arranged PRPD data.

The processor may be configured to identify feature information of the waveform of each PRPD data according to the identified pattern, and arrange the plurality of pieces of PRPD data in chronological order based on the identified feature information.

The processor may be configured to identify a partial discharge propagation path based on the installation locations of the plurality of data acquisition apparatuses and the plurality of pieces of arranged PRPD data, and identify the partial discharge occurrence location through the partial discharge propagation path.

The processor may be configured to identify the partial discharge occurrence location based on a model trained to perform an operation on the partial discharge occurrence location according to the installation locations of the plurality of data acquisition apparatuses and the plurality of pieces of arranged PRPD data.

The processor may be configured to identify the partial discharge occurrence location when the patterns corresponding to the plurality of pieces of PRPD data are all identified as the same pattern.

The sensor data processor may be configured to receive the periodically updated time synchronization signal from the precision time synchronizer.

According to an embodiment of the present disclosure, precise time synchronization-based partial discharge occurrence location determination algorithms can increase the efficiency of facility investment not only in connection with power facility protection and relay systems, but also in abnormal situations in power facilities where various abnormal phenomena may coexist.

According to an embodiment of the present disclosure, it is possible to more accurately identify the partial discharge occurrence location through simultaneously collected sensing data.

### BRIEF DESCRIPTION OF THE DRAWINGS

FIG. 1 is a diagram illustrating a system for estimating a partial discharge occurrence location according to an embodiment of the present disclosure.

FIG. 2 is a block diagram illustrating a configuration of a data acquisition apparatus according to an embodiment of the present disclosure.

FIG. 3 is a block diagram illustrating a configuration of a determination apparatus according to an embodiment of the present disclosure.

FIG. 4 is a diagram illustrating time precise synchronization according to an embodiment of the present disclosure.

FIG. 5 is a diagram illustrating PRPD data according to an embodiment of the present disclosure.

FIG. 6 is a diagram illustrating an operation flowchart of a determination apparatus according to an embodiment of the present disclosure.

FIG. 7 is a diagram illustrating a waveform of PRPD data according to an embodiment of the present disclosure.

### DETAILED DESCRIPTION

Hereinafter, preferred embodiments according to the present disclosure will be described in detail with reference to the accompanying drawings. The detailed description to be disclosed hereinafter with the accompanying drawings is intended to describe exemplary embodiments of the present disclosure and is not intended to represent the only embodiments in which the present disclosure may be implemented. In the drawings, parts unrelated to the description may be omitted for clarity of description of the present disclosure, and like reference numerals may designate like elements throughout the specification.

The present disclosure relates to a system for measuring partial discharge phenomena that may occur in electric power facilities used in industrial sites, and more particularly, to a system that can more precisely identify the location where partial discharge occurs using network-based time synchronization technology implemented through PTP. This will be described in detail below.

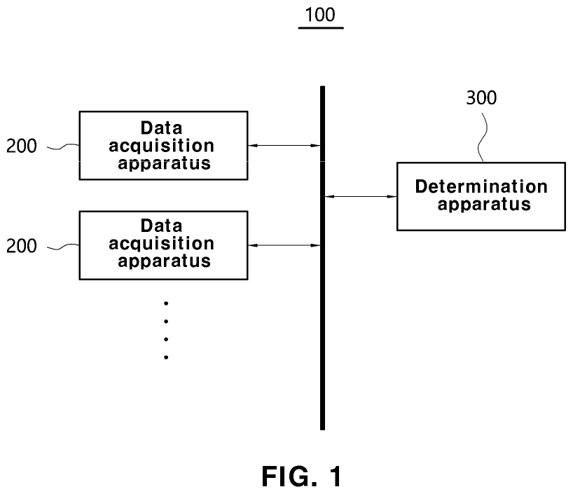

FIG. 1 is a diagram illustrating a system for estimating a partial discharge occurrence location according to an embodiment of the present disclosure.

FIG. 1 schematically illustrates a system 100 for estimating a partial discharge occurrence location (hereinafter referred to as system 100), and the system 100 according to an embodiment of the present disclosure includes a plurality of data acquisition apparatuses 200 and a determination apparatus 300.

The data acquisition apparatus 200 is installed in one area of a measurement target and measures high frequencies generated from the target to be measured. The data acquisition apparatus 200 includes a sensor, and the type of sensor to be used may vary depending on the insulation characteristics where partial discharge occurs. Therefore, the sensor can be appropriately selected according to the frequency band of electromagnetic waves generated from partial discharge. The measurement target is a high-voltage power facility, and may be, for example, a switchboard, an oil-immersed type transformer, a gas insulated switchgear (GIS), etc., but is not limited to any one.

A plurality of data acquisition apparatuses 200 are each installed in one area of a measurement target to acquire sensing data. In identifying the location of partial discharge, synchronization of the time when sensing data is measured by each data acquisition apparatus 200 is a very important factor. The location where the partial discharge occurs can be identified based on the propagation path through which the partial discharge is detected, and the propagation path can be obtained by arranging the data detected from the plurality of data acquisition apparatuses 200 in chronological order. That is, since the waveform of the partial discharge appears in the sensing data in the order of the data acquisition apparatuses 200 installed in a location close to the location where the partial discharge occurred, it is difficult to know how the propagation path was formed if the measurement times of the data acquisition apparatuses 200 are different.

In this case, if 16.67 msec per cycle is set at 60 Hz and approximately 120 pieces of sensing data are collected per cycle, the cycle of collecting sensing data is set in microseconds. Therefore, the Network Time-synchronization Protocol (NTP), which allows time synchronization down to the millisecond (ms) level, cannot be utilized, so in the present disclosure, time synchronization is performed using the Precision Time-synchronization Protocol (PTP), which allows time synchronization down to the nanosecond (ns) level.

The determination apparatus 300 receives a plurality of pieces of sensing data measured at the same time from the plurality of data acquisition apparatuses 200, and determines a partial discharge occurrence location of the measurement target by using the plurality of pieces of received sensing data.

Detailed information regarding the configuration and operation of the data acquisition apparatus 200 and the determination apparatus 300 will be described with reference to the drawings below.

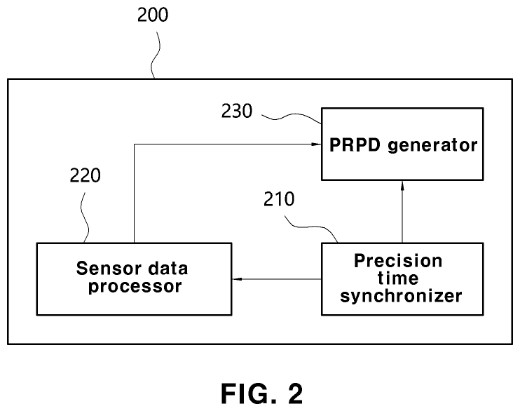

FIG. 2 is a block diagram illustrating a configuration of a data acquisition apparatus 200 according to an embodiment of the present disclosure.

The data acquisition apparatus 200 according to an embodiment of the present disclosure includes a precision time synchronizer 210, a sensor data processor 220, and a PRPD (Phase Resolved Partial Discharge) generator 230.

The precision time synchronizer 210 according to an embodiment of the present disclosure transmits a time synchronization signal based on PTP based on a master apparatus.

The precision time synchronizer 210 includes PTP software and configures a network for reference time and time synchronization through a LAN network. The precision time synchronizer 210 performs the function of synchronizing the system clocks of the plurality of data acquisition apparatuses 200 to the reference time by performing PTP, and adjusts the control timing using 1 PPS (pulse per second).

According to an embodiment of the present disclosure, a plurality of data acquisition apparatuses 200 connected to the same network can be time synchronized using a precise time synchronization algorithm provided by PTP. The precise time synchronization algorithm can operate in either master or slave mode. In the present disclosure, the data acquisition apparatus 200 operating in master mode is referred to as a master apparatus, and the data acquisition apparatus 200 operating in slave mode is referred to as a slave apparatus. In this case, since there is only one master apparatus that can exist simultaneously in one network, the remaining plurality of slave apparatuses synchronize their times based on this one master apparatus. In this case, since the plurality of data acquisition apparatuses 200 are apparatuses that perform the same function and have no priority, there is no limit to the criteria for selecting the master apparatus.

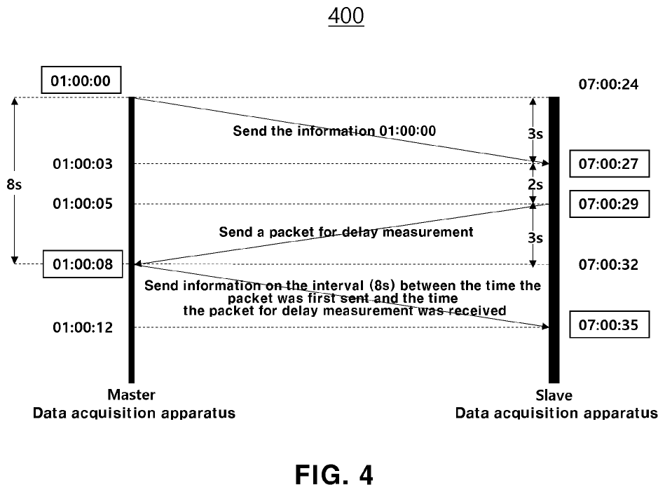

PTP basically compensates for the network path delay through 2-step time information exchange and performs synchronization of the clock frequency based on the time synchronization correction information value. Details about time synchronization are described in relation to FIG. 4.

By synchronizing time based on the master apparatus, the precision time synchronizer 210 of the plurality of data acquisition apparatuses 200 can transmit a time synchronization signal to the sensor data processor 220 at the same timing. In addition, the precision time synchronizer 210 may transmit a time synchronization signal to be used when generating PRPD data to the PRPD generator 230.

The sensor data processor 220 according to an embodiment of the present disclosure may collect sensing data based on a time synchronization signal received from the precision time synchronizer 210 and process the collected sensing data. Sensing data refers to data that detects high frequencies generated when partial discharge occurs in a measurement target.

The sensor data processor 220 may perform analog/digital (A/D) conversion that converts the sensing data of the collected analog signals into digital signals. Additionally, the sensor data processor 220 may perform sampling by cutting the waveform appearing in the sensing data based on the phase from 0 degrees to 360 degrees.

The sensor data processor 220 transmits the sampled sensing data to the PRPD generator 230. In this case, the transmission cycle may be based on one cycle of the power line supplied to the sensor data processor 220. For example, if the signal coming through the power line comes at 60 Hz, 1 cycle is 16.67 msec.

According to an embodiment of the present disclosure, A/D conversion or sampling can be performed using an FPGA board or by installing a separate CPU for DSP.

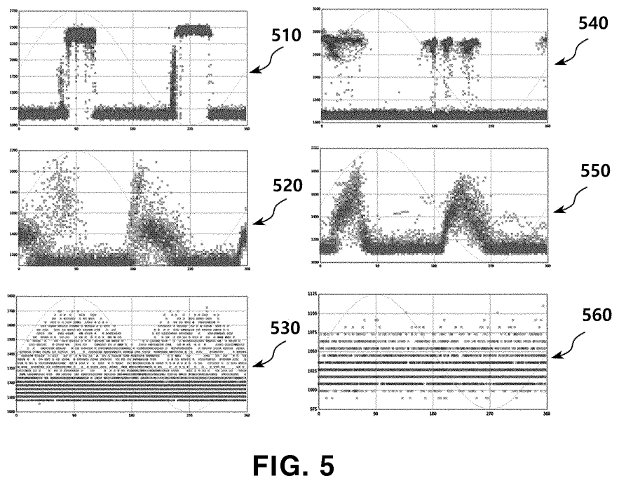

The PRPD generator 230 according to an embodiment of the present disclosure generates PRPD data by mapping a plurality of pieces of processed sensing data received from the sensor data processor 220 for a predefined time and a time synchronization signal received from the precision time synchronizer 210. A specific example of PRPD data is shown in FIG. 5.

The PRPD generator 230 receives a plurality of pieces of processed sensing data from the sensor data processor 220 for a predefined time. That is, as described above, the sensor data processor 220 transmits sensing data to the PRPD generator 230 every 1 cycle based on the power frequency, and the PRPD generator 230 takes the sensing data received every 1 cycle as one phase (0 to 360 degrees) and accumulates it for a predefined time. In this case, the predefined time may be 1 second, but is not limited thereto.

The PRPD generator 230 generates PRPD data according to the PRPD data format from the plurality of pieces of accumulated sensing data and then transmits it to the determination apparatus 300. In this case, the PRPD generator 230 generates PRPD data by mapping the time synchronization signal received from the precision time synchronizer 210 to the accumulated plurality of pieces of sensing data. More specifically, the PRPD generator 230 may tag the time at which the sensing data included in the time synchronization signal was collected.

To this end, the precision time synchronizer 210 may transmit a time synchronization signal to the PRPD generator 230. Alternatively, the OS time at the moment the precision time synchronizer 210 transmits the time synchronization signal to the sensor data processor 220 can be used as time information mapped to PRPD data to synchronize to the same time axis.

In this case, since all sampled sensing data have the same length, the collection time of sensing data accumulated in one generated PRPD data can be calculated based on one sensing data, so the time at which any one sensing data was collected can be tagged.

According to an embodiment of the present disclosure, the plurality of data acquisition apparatuses 200 allow the sensing data processors 210 of all data acquisition apparatuses 200 to collect sensing data at the same time using PTP, and include information on the collection time in the PRPD data to be analyzed by the determination apparatus 300, so it is possible to collect analysis data to more accurately identify the location of partial discharge.

If one measuring equipment does not satisfy the number of data acquisition apparatuses required to determine the partial discharge occurrence location, the hardware-based interrupt unification proposed in the present disclosure enables simultaneous data measurement without being limited to the number of data acquisition apparatuses.

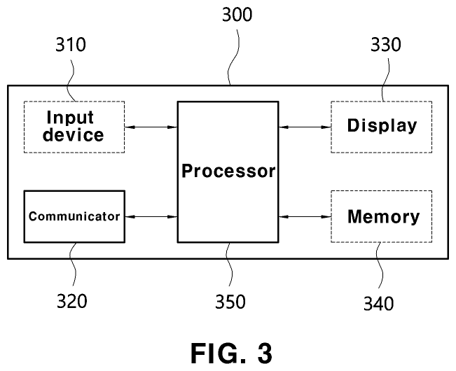

FIG. 3 is a block diagram illustrating a configuration of a determination apparatus according to an embodiment of the present disclosure.

The determination apparatus 300 for determining the partial discharge occurrence location of a measurement target according to an embodiment of the present disclosure includes an input device 310, a communicator 320, a display 330, a memory 340, and a processor 350.

The input device 310 generates input data in response to a user input of the determination apparatus 300. The input device 310 includes at least one input means. The input device 310 may include a keyboard, a keypad, a dome switch, a touch panel, a touch key, a mouse, a menu button, and the like.

The communicator 320 performs communication for receiving a plurality of pieces of PRPD data from a plurality of data acquisition apparatuses 200. To this end, the communicator 320 may perform communications such as Ethernet, 5th generation communication (5G), long term evolution-advanced (LTE-A), long term evolution (LTE), and wireless fidelity (Wi-Fi).

The display 330 displays display data according to the operation of the determination apparatus 300. The display 330 includes a liquid crystal display (LCD), a light emitting diode (LED) display, an organic light emitting diode (OLED) display, a micro electro mechanical systems (MEMS) display, and an electronic paper display. The display 330 may be combined with the input device 310 to be implemented as a touch screen.

The memory 340 stores operation programs of the determination apparatus 300. The memory 340 includes a non-volatile storage for storing data (information) regardless of whether power is supplied or not, and a volatile memory in which data to be processed by the processor 350 is loaded and cannot retain data unless power is provided. The storage includes a flash memory, a hard-disc drive (HDD), a solid-state drive (SSD), a read only memory (ROM), and the like, and the memory includes a buffer and a random access memory (RAM), and the like.

The memory 340 may store PRPD data or information about patterns corresponding to the PRPD data. In addition, the memory 340 may store information about a model trained to perform calculations on the partial discharge occurrence location according to the pattern and propagation path corresponding to the PRPD data.

The processor 350 may execute software, such as a program, to control at least one other component (e.g., hardware or software component) of the determination apparatus 300, and may perform various data processing or calculations.

For example, the processor 350 may perform an operation to: receive a plurality of pieces of PRPD data from a plurality of data acquisition apparatuses through the communicator 320, identify a pattern corresponding to the plurality of pieces of received PRPD data, arrange the plurality of pieces of PRPD data in chronological order based on the mapped time synchronization signal, and identify the partial discharge occurrence location based on the installation locations of the plurality of data acquisition apparatuses and the plurality of pieces of arranged PRPD data.

The processor 350 may perform at least some of the data analysis, processing, and result information generation for performing calculations on the partial discharge occurrence location using at least one of machine learning, a neural network, and a deep learning algorithm as a rule-based or artificial intelligence algorithm. Examples of the neural network may include a model such as a convolutional neural network (CNN), a deep neural network (DNN), and a recurrent neural network (RNN).

That is, the accuracy of analysis can be increased by applying AI techniques to identify the location of partial discharges along standardized propagation paths for each power facility such as switchboard, Tr, and GIS.

FIG. 4 is a diagram illustrating time precise synchronization according to an embodiment of the present disclosure. FIG. 4 describes time synchronization in the precision time synchronizer 210 of the data acquisition apparatus 200 described in relation to FIG. 2.

Network-based time synchronization technology implemented through PTP uses an Ethernet port that supports time-stamping.

Therefore, time stamping for each packet containing information for time synchronization between the data acquisition apparatuses 200 is provided from the Ethernet port, not from the OS level that performs processing, such as the CPU within the data acquisition apparatus 200.

The background of supporting time stamping on the Ethernet port is that even if the data acquisition apparatus 200 receives the packet, it may take time for the time-synchronized packet to be delivered from the Ethernet port to the OS level that performs processing such as the sensor data processor 210 in the data acquisition apparatus 200. In addition, there is a delay in identifying information contained in the actual packet depending on OS level scheduling and packet processing order. Therefore, for precise time synchronization, the time of the moment it arrives at the Ethernet port is stamped and inserted into the packet header.

The packets acquired in this way satisfy the hardware conditions required for nanosecond level time synchronization in the PTP standard.

FIG. 4 illustrates a flowchart 400 of time synchronization between apparatuses based on a master apparatus. In this case, it is described in seconds(s), but this is just an example to show that time synchronization is performed, and it is natural that it can also be implemented in nanosecond (ns) units. The following operations can be performed by the precision time synchronizer 210 of each data acquisition apparatus 200.

The times described in the flowchart 400 refer to the time when packets are transmitted or received at the Ethernet ports of the master apparatus and the slave apparatus, and in particular, the boxed time refers to the time when time stamping is required.

First, the master apparatus sent a packet containing the information 01:00:00 at 01:00:00, and the packet was received at 07:00:27 through the Ethernet port of the slave apparatus.

Again, the slave apparatus transmitted a packet for delay measurement at 07:00:29 through the Ethernet port of the slave apparatus, and the master apparatus received the packet for delay measurement at 01:00:08 through the Ethernet port of the master apparatus.

The master apparatus again sends a packet containing information of 8 s, which is the interval from the time the first packet was sent (01:00:00) to the time the packet for delay measurement was received (01:00:08), to the slave apparatus.

The slave apparatus can calculate the delay time (3 s) by subtracting 2 s from 8 s and dividing the remaining 6 s by 2. That is, since the slave apparatus received the information 01:00:00 at 07:00:27, it identifies that it can synchronize to 01:00:03 at this time. The slave apparatus synchronizes the current time to the master apparatus by applying it to the current time (07:00:35).

However, even if such synchronization work is performed, there is a possibility that the synchronization may be lost again after a certain period of time. Accordingly, the sensor data processor 220 receives the periodically updated time synchronization signal from the precision time synchronizer 210. The cycle of updating the time synchronization signal can be optimized for the field from 1 ms to 16 s.

According to an embodiment of the present disclosure, precise partial discharge location identification is possible by enabling network-based time synchronization between a plurality of data acquisition apparatuses.

FIG. 5 is a diagram illustrating PRPD data according to an embodiment of the present disclosure.

The PRPD data of FIG. 5 is generated by the PRPD generator 230 of the data acquisition apparatus 200 of FIG. 2 described above. A PRPD pattern that can be identified from PRPD data is formed by 120 dots per phase. Hereinafter, occurrence patterns 510 to 560 identified from PRPD data will be described. The data was created from sensing data collected by partial discharge of GIS.

Corona pattern 510 mainly generates signals around a phase of 90 degrees or 270 degrees. The corona pattern 510 occurs in conductor protrusions formed on protruding conductor parts, high voltage parts, or grounding part conductors under abnormal surrounding environmental conditions.

Void pattern 520 generates signals around a phase of 0 degrees to 70 degrees, 175 degrees to 230 degrees, and 360 degrees. The void pattern 520 is caused by voids or foreign matter inside the insulator, voids between the busbar and the barrier, internal defects in the CT insulator, and defects in the cable insulation.

Free moving particle pattern 530 generates signals in all phases and occurs in the free conductor inside the GIS, the bottom of the CB/DS, and the conductor powder formation area due to mechanical vibration.

Floating electrode pattern 540 generates signals at a phase of 15 degrees to 40 degrees, 60 degrees to 70 degrees, 200 degrees to 210 degrees, and 250 degrees. The floating electrode pattern 540 occurs due to loosening of a bolt, penetration of floating foreign matter, foreign matter on a conductor inside the CT or busbar insulator, or a conductor in an ungrounded state.

Surface defect pattern 550 generates signals around a phase of 10 degrees to 80 degrees and 190 degrees to 270 degrees. The surface defect pattern 550 occurs in damaged insulators (insulators, barriers) and aged insulators (busbars, barriers).

External noise pattern 560 generally generates signals in all phases and are caused by external signal input due to the use of electric motors or radios.

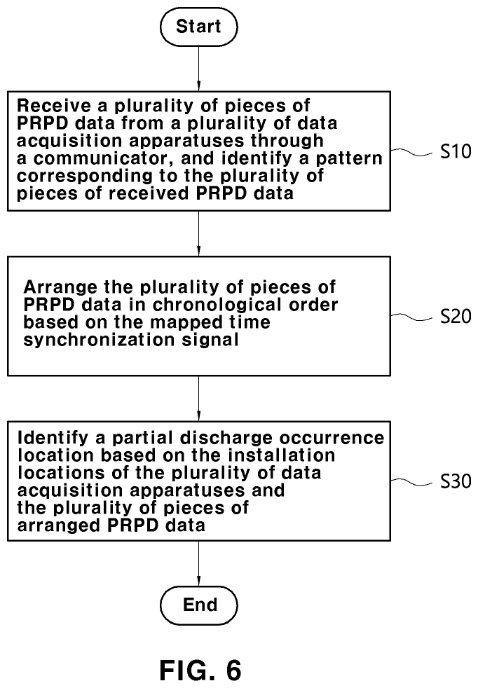

FIG. 6 is a diagram illustrating an operation flowchart of a determination apparatus according to an embodiment of the present disclosure.

The processor 350 according to an embodiment of the present disclosure may receive a plurality of pieces of PRPD data from the plurality of data acquisition apparatuses 200 through the communicator 320, and identify a pattern corresponding to the plurality of pieces of received PRPD data in step S10.

The pattern corresponding to the plurality of pieces of PRPD data is the same as previously described in FIG. 5.

The processor 350 determines tagged time information based on a time synchronization signal mapped to the plurality of pieces of PRPD data, and identifies PRPD data with the same tagged time as a set.

The processor 350 prepares to identify the partial discharge occurrence location when the patterns corresponding to the plurality of pieces of PRPD data generated based on the same time synchronization signal are all identified as the same pattern. However, it is not limited thereto, and when eight data acquisition apparatuses are installed in the measurement target, two or more different types of partial discharge may occur, or the same pattern may not appear due to a measurement error of any one of the data acquisition apparatuses, so it may be appropriately determined according to the situation.

The processor 350 according to an embodiment of the present disclosure may arrange the plurality of pieces of PRPD data in chronological order based on the time synchronization signal mapped to the plurality of pieces of PRPD data in step S20.

In this case, the processor 350 may identify feature information of the waveform of each PRPD data according to the identified pattern, and arrange the plurality of pieces of PRPD data in chronological order based on the identified feature information.

Electromagnetic waves generated from partial discharge are detected later as they move away from the location and faster as they get closer, so it is possible to estimate the propagation path of partial discharge using these characteristics and determine the partial discharge occurrence location.

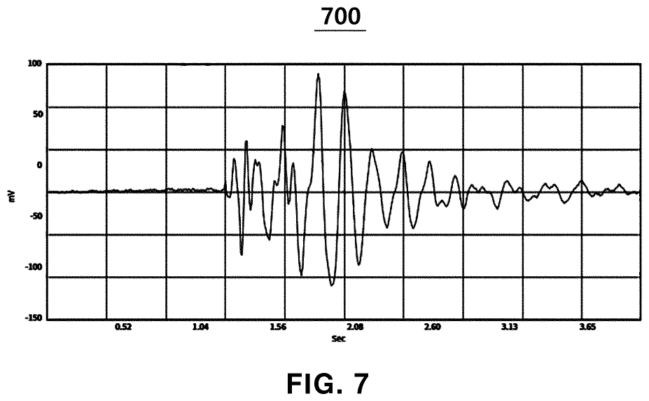

FIG. 7 is a diagram illustrating a waveform 700 of PRPD data according to an embodiment of the present disclosure, and will be understood with reference to this. A PRPD pattern that can be identified from PRPD data is formed by 120 dots per phase, and the processor 350 identifies a waveform of approximately 50 microseconds by increasing the resolution of the dot with the highest value among 120 dots per cycle to 1 dot per 10 nanoseconds.

The feature information of the waveform includes information about the peak value or inflection point section of each PRPD data waveform in the PRPD data set.

The time at which the waveform generated by the partial discharge is detected in the PRPD data received from each data acquisition apparatus 200 is inevitably different depending on the distance between the location where the partial discharge occurred and the locations of a plurality of data acquisition apparatuses 200 installed in various places of the measurement target.

Therefore, characteristic waveforms that commonly appear within the PRPD data set are identified, and the PRPD data is arranged in chronological order according to the time the waveform was recorded.

The processor 350 according to an embodiment of the present disclosure may identify the partial discharge occurrence location based on the installation location of the plurality of data acquisition apparatuses 200 and the plurality of pieces of PRPD data arranged in chronological order in step S30.

More specifically, the processor 350 may identify a partial discharge propagation path based on the installation location of the plurality of data acquisition apparatuses 200 and the plurality of pieces of PRPD data arranged in chronological order. The partial discharge propagation path refers to the path where partial discharge is observed based on the installation locations of the plurality of data acquisition apparatuses 200, and the processor 350 may identify the partial discharge propagation path by arranging them in order starting from the time when the partial discharge was observed most quickly.

In this case, the processor 350 may identify the partial discharge occurrence location based on a model trained to perform an operation on the partial discharge occurrence location according to the installation locations of the plurality of data acquisition apparatuses 200 and the plurality of pieces of PRPD data arranged in chronological order. That is, the location of partial discharge along the propagation path may be standardized for each power facility, and this may be trained in a model.

According to an embodiment of the present disclosure, to build a digital and smart automated substation environment, precise time synchronization-based partial discharge data acquisition and partial discharge occurrence location determination algorithms enable network-based time synchronization between various electronic equipment that make up the substation. Therefore, it can increase the efficiency of facility investment not only in connection with power facility protection and relay systems, but also in abnormal situations in power facilities where various abnormal phenomena may coexist.

1. A system for estimating a partial discharge occurrence location, comprising:
a plurality of data acquisition apparatuses that are installed in one area of a measurement target, and simultaneously acquire sensing data via time synchronization using a precision time-synchronization protocol (PTP); and
a determination apparatus that determines a partial discharge occurrence location of the measurement target by using a plurality of pieces of sensing data received from the plurality of data acquisition apparatuses.

2. The system of claim 1,
wherein the plurality of data acquisition apparatuses consist of one master apparatus and a plurality of slave apparatuses, and
each of the plurality of data acquisition apparatuses comprises:
a precision time synchronizer configured to transmit a time synchronization signal based on PTP based on the master apparatus;
a sensor data processor configured to collect the sensing data based on a time synchronization signal received from the precision time synchronizer and process the collected sensing data; and
a PRPD generator configured to generate PRPD data by mapping the plurality of pieces of processed sensing data received from the sensor data processor for a predefined time and a time synchronization signal received from the precision time synchronizer.

3. The system of claim 2,
wherein the determination apparatus comprises:
a communicator; and
a processor configured to:
receive the plurality of pieces of PRPD data from the plurality of data acquisition apparatuses through the communicator,
identify a pattern corresponding to the plurality of pieces of received PRPD data,
arrange the plurality of pieces of PRPD data in chronological order based on the mapped time synchronization signal, and
identify the partial discharge occurrence location based on the installation locations of the plurality of data acquisition apparatuses and the plurality of pieces of arranged PRPD data.

4. The system of claim 3,
wherein the processor is configured to:
identify feature information of the waveform of each PRPD data according to the identified pattern, and
arrange the plurality of pieces of PRPD data in chronological order based on the identified feature information.

5. The system of claim 3,
wherein the processor is configured to:
identify a partial discharge propagation path based on the installation locations of the plurality of data acquisition apparatuses and the plurality of pieces of arranged PRPD data, and
identify the partial discharge occurrence location through the partial discharge propagation path.

6. The system of claim 5,
wherein the processor is configured to:
identify the partial discharge occurrence location based on a model trained to perform an operation on the partial discharge occurrence location according to the installation locations of the plurality of data acquisition apparatuses and the plurality of pieces of arranged PRPD data.

7. The system of claim 3,
wherein the processor is configured to:
identify the partial discharge occurrence location when the patterns corresponding to the plurality of pieces of PRPD data are all identified as the same pattern.

8. The system of claim 2,
wherein the sensor data processor is configured to:
receive the periodically updated time synchronization signal from the precision time synchronizer.
